(19) United States
(12) Patent Application Publication
(10) Pub. No.: US 2024/0332047 A1
(43) Pub. Date: Oct. 3, 2024

(54) SUBSTRATE PROCESSING APPARATUS

(71) Applicant: Tokyo Electron Limited, Tokyo (JP)

(72) Inventors: Yoshitaka MIURA, Oshu City (JP); Tomoyuki NAGATA, Oshu City (JP)

(21) Appl. No.: 18/610,344

(22) Filed: Mar. 20, 2024

(30) Foreign Application Priority Data
Mar. 28, 2023 (JP) 2023-051771

(51) Int. Cl. H01L 21/67

(52) U.S. Cl. CPC H01L 21/67248; H01L 21/67017; H01L 21/6719; H01L 21/67253

(57) ABSTRACT

A substrate processing apparatus includes: a process container accommodating a substrate holder that holds a plurality of substrates and including an opening at a lower end of the process container; a lid configured to open and close the opening; and a thermal insulator installed on the lid and configured to thermally insulate a first space below the substrate holder. The thermal insulator includes a partition member that forms a second space partitioned from the first space. The lid includes a supply port for supplying a temperature regulation fluid to the second space and an exhaust port for discharging the temperature regulation fluid from the second space.

### CROSS-REFERENCE TO RELATED APPLICATION

This application is based upon and claims the benefit of priority from Japanese Patent Application No. 2023-051771, filed on Mar. 28, 2023, the entire contents of which are incorporated herein by reference.

### TECHNICAL FIELD

The present disclosure relates to a substrate processing apparatus.

### BACKGROUND

There is known a substrate processing apparatus in which a substrate holder that holds substrates arranged in multiple stages is accommodated in a reaction container having an opening at a lower end of the reaction container, and the substrates are subjected to heat treatment in a state in which the opening is closed by a lid (e.g., see Patent Document 1). In Patent Document 1, a cover section covering the lid is provided, and a thermal insulator is installed in a space covered by the cover section.

### PRIOR ART DOCUMENT

### Patent Document

Patent Document 1: Japanese Patent Publication No. 6736755

### SUMMARY

According to one embodiment of the present disclosure, there is provided a substrate processing apparatus including: a process container accommodating a substrate holder that holds a plurality of substrates and including an opening at a lower end of the process container; a lid configured to open and close the opening; and a thermal insulator installed on the lid and configured to thermally insulate a first space below the substrate holder. The thermal insulator includes a partition member that forms a second space partitioned from the first space. The lid includes a supply port for supplying a temperature regulation fluid to the second space and an exhaust port for discharging the temperature regulation fluid from the second space.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating a substrate processing apparatus according to a first embodiment.

FIG. 2 is a cross-sectional view taken in a direction of an arrow II-II in FIG. 1.

FIG. 3 is a cross-sectional view taken in a direction of an arrow III-III in FIG. 1.

FIG. 4 is a perspective view of a plate viewed obliquely from above.

FIG. 5 is a cross-sectional view illustrating a substrate processing apparatus according to a second embodiment.

FIG. 6 is a cross-sectional view illustrating a substrate processing apparatus according to a third embodiment.

FIG. 7 is a cross-sectional view illustrating a substrate processing apparatus according to a fourth embodiment.

FIG. 8 is a cross-sectional view illustrating a substrate processing apparatus according to a fifth embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure will be described with reference to the accompanying drawings. In all the accompanying drawings, the same or corresponding members or components will be denoted by the same or corresponding reference numerals, and redundant descriptions thereof will be omitted.

### First Embodiment

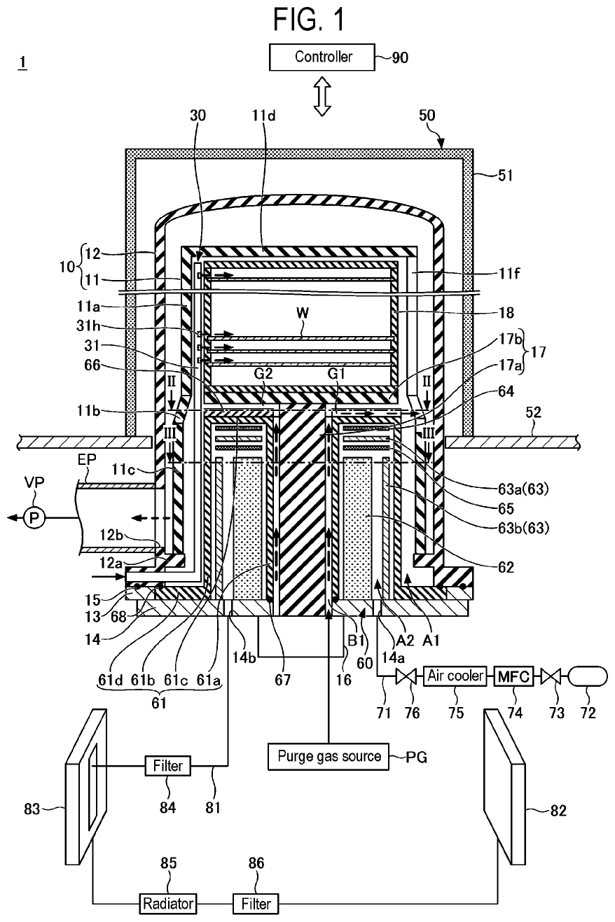

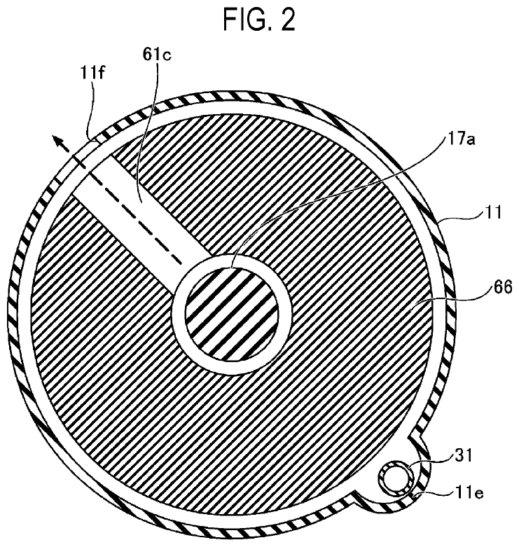

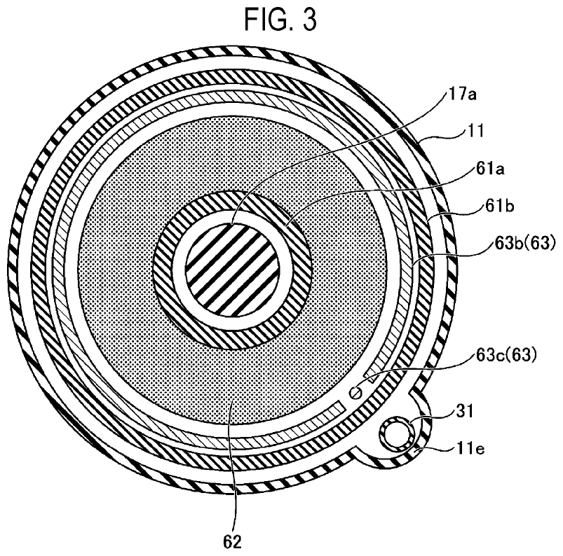

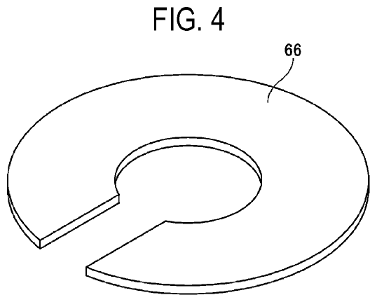

A substrate processing apparatus 1 according to a first embodiment will be described with reference to FIGS. 1 to 4. FIG. 1 is a cross-sectional view illustrating the substrate processing apparatus 1 according to the first embodiment. FIG. 2 is a cross-sectional view taken in a direction of an arrow II-II in FIG. 1. FIG. 3 is a cross-sectional view taken in a direction of an arrow III-III in FIG. 1. FIG. 4 is a perspective view of a plate 66 viewed obliquely from above.

The substrate processing apparatus 1 is a batch type heat treatment apparatus that performs heat treatment on multiple substrates W at once. The substrates W are, for example, semiconductor wafers. The substrate processing apparatus 1 includes a process container 10, a gas supplier 30, a heater 50, a thermal insulator 60, and a controller 90.

An interior of the process container 10 is depressurizable. The process container 10 accommodates the substrates W in the interior thereof. The process container 10 includes an inner tube 11 and an outer tube 12.

The inner tube 11 has a cylindrical shape, and includes an open lower end and a ceiling. The outer tube 12 has a cylindrical shape, and includes an open lower end and a ceiling covering an exterior of the inner tube 11. The inner tube 11 and outer tube 12 are arranged coaxially to have a dual-tube structure. Both the inner and outer tubes 11 and 12 are made of, for example, quartz.

The inner tube 11 has a first cylindrical portion 11a, an enlarged diameter portion 11b, a second cylindrical portion 11c, and a ceiling plate 11d. The first cylindrical portion 11a, the enlarged diameter portion 11b, and the second cylindrical portion 11c are provided in this order from above to below. The first cylindrical portion 11a is provided to encompass a height area from a position above an upper end of a substrate holder 18 to a lower end of the substrate holder 18, which will be described later. The first cylindrical portion 11a has a first inner diameter. The enlarged diameter portion 11b is located below the first cylindrical portion 11a. The enlarged diameter portion 11b is enlarged in diameter from the first inner diameter to a second inner diameter from above to below. The second inner diameter is larger than the first inner diameter. The second cylindrical portion 11c is located below the enlarged diameter portion 11b. The second cylindrical portion 11c has the second inner diameter. The ceiling plate 11d closes an opening at an upper end of the first cylindrical portion 11a.

The inner tube 11 has a protrusion 11e, which protrudes outward from a portion of a sidewall of the inner tube 11. The protrusion 11e is formed along a longitudinal direction (vertical direction) of the inner tube 11. In the protrusion 11e, an accommodating region accommodating a gas injector 31, which will be described later, is formed. A rectangular exhaust port 11f is formed in the sidewall of the inner tube 11 opposite to the protrusion 11e to extend in the vertical direction. Specifically, the exhaust port 11f is formed in the inner tube 11 to extend from the first cylindrical portion 11a to a vicinity of an upper end of the second cylindrical portion 11c. A processing gas inside the process container 10 is discharged through the exhaust port 11f.

The lower end of the outer tube 12 is supported by an annular flange member 13, which is made of, for example, stainless steel, and is airtightly installed via a seal member 15 such as an O-ring. An annular plate-shaped support 12a is provided at a lower portion on an inner wall of the outer tube 12. The support 12a supports the lower end of the inner tube 11. A gas outlet 12b is provided on a sidewall of the outer tube 12 immediately above the support 12a. An exhaust pipe EP is connected to the gas outlet 12b. A pressure adjustment valve (not illustrated) and a vacuum pump VP are interposed and installed in the exhaust pipe EP in this order. A lid 14 is airtightly installed to a lower end of the annular flange member 13 via a seal member (not illustrated) such as an O-ring. The lid 14 airtightly closes an opening at a lower end of the process container 10, i.e., an opening of the outer tube 12. The lid 14 is made of, for example, a metal such as stainless steel.

A rotator 16 is installed on a central portion of the lid 14. The rotator 16 includes, for example, a magnetic fluid seal. An arm (not illustrated) of an elevator, specifically, a boat elevator, is connected to a bottom of the rotator 16. The rotator 16 is moved vertically by raising or lowering the arm. A support 17 is connected to a top of the rotator 16. The support 17 is rotatable relative to the lid 14. The support 17 is made of, for example, quartz. The support 17 includes a shaft 17a and a stage 17b. A bottom of the shaft 17a is connected to the rotator 16. The stage 17b is located at a top of the shaft 17a. The stage 17b has a disc shape having a diameter larger than a diameter of the shaft 17a in a plan view from above. The stage 17b supports the substrate holder 18. The substrate holder 18 holds multiple substrates W (e.g., 25 to 200 substrates W), which are arranged in multiple stages in the vertical direction with a horizontal posture. The substrate holder 18 is made of, for example, quartz or silicon carbide. The substrate holder 18 is vertically moved, as an integral body with the lid 14, the rotator 16, and the support 17, by raising or lowering the arm. This allows the substrate holder 18 to be inserted into and removed from the process container 10.

The gas supplier 30 includes the gas injector 31. The gas injector 31 extends linearly near an inner surface of the inner tube 11 along an arrangement direction (vertical direction) of the substrates W, and is bent into an L-shape at a bottom portion of the inner tube 11 to pass through the outer tube 12 and extend to the outside of the inner tube 11. The gas injector 31 is made of quartz, for example. An end of the gas injector 31 outside the inner tube 11 is connected to a gas source (not illustrated) for the processing gas via a gas supply path (not illustrated). Gas discharge holes 31h are formed in a portion of the gas injector 31 located in the interior of the inner tube 11. Each gas discharge hole 31h is disposed at a predetermined interval along a direction in which the gas injector 31 extends. The processing gas from the gas source is introduced into the gas injector 31 via the gas supply path and is discharged into the inner tube 11 from each gas discharge hole 31h. The inner diameter of the inner tube 11 is reduced in a height area where the substrate holder 18 is located, and the inner tube 11 is further includes an exhaust port 11f opposite to the gas injector 31. In this case, it is possible to promote a flow of the processing gas discharged from each gas discharge hole 31h toward the substrate W. A gap between the respective adjacent gas discharge holes 31h is set, for example, to be the same as a gap between the respective adjacent substrates W held by the substrate holder 18. A position of each gas discharge hole 31h in the height direction is set, for example, to an intermediate position between the adjacent substrates W in the vertical direction. In this case, it is possible to allow each gas discharge hole 31h to efficiently supply the processing gas to opposing surfaces of the adjacent substrates W.

The gas supplier 30 may be adapted to mix multiple types of processing gases and to discharge a mixture of the processing gases from a single gas injector. The gas supplier 30 may also include other gas injectors to discharge different processing gases, in addition to the gas injector 31.

The heater 50 includes a chamber heater 51. The chamber heater 51 surrounds the process container 10 at the radial outside of the process container 10 and has a cylindrical shape with a ceiling covering a ceiling of the process container 10. The chamber heater 51 is fixed on a base plate 52. The chamber heater 51 heats a periphery and the ceiling of the process container 10, thereby heating each substrate W accommodated in the process container 10.

The thermal insulator 60 includes a partition member 61, a thermal insulator 62, a heater 63, a radiation panel 64, a reflector 65, and a plate 66.

The partition member 61 is installed on the lid 14. The partition member 61 is located in the interior of the process container 10 when the opening at the lower end of the process container 10 is airtightly closed by the lid 14. The partition member 61 is made of, for example, quartz. The partition member 61 includes an inner wall 61a, an outer wall 61b, a ceiling wall 61c, and a flange 61d.

The inner wall 61a is installed around the shaft 17a. The inner wall 61a has a cylindrical shape. A lower end of the inner wall 61a is installed on the lid 14 via a seal member 67 such as an O-ring. A narrow space B1 is provided between an inner surface of the inner wall 61a and an outer surface of the shaft 17a. A purge gas is supplied to the narrow space B1 from a purge gas source PG. The purge gas is supplied upward from below the process container 10. The purge gas prevents the processing gas discharged into the inner tube 11 from being introduced into the rotator 16. The purge gas is, for example, a nitrogen gas.

The outer wall 61b is installed around the inner wall 61a. The outer wall 61b has a cylindrical shape. The outer wall 61b is provided coaxially with the inner wall 61a. A lower end of the outer wall 61b is installed on the lid 14.

The ceiling wall 61c connects an upper end of the inner wall 61a to an upper end of the outer wall 61b, thus closing a top of a space between the inner wall 61a and the outer wall 61b. The ceiling wall 61c has an annular plate shape. In conjunction with the lid 14, the inner wall 61a, and the outer wall 61b, the ceiling wall 61c forms a second space A2 partitioned from a first space A1 in the interior of the process container 10. The first space A1 is switched between an atmospheric atmosphere and a vacuum atmosphere. The second space A2 is an environment outside the process container 10. The second space A2 is maintained in an atmospheric atmosphere or an inert gas atmosphere, for example. An inert gas is, for example, a nitrogen gas. The ceiling wall 61c is opposite to the stage 17b with a gap interposed between the ceiling wall 61c and the stage 17b.

The flange 61d extends outward from the bottom of the outer wall 61b. A seal member 68 such as an O-ring is provided between an upper surface of an outer edge of the flange 61d and the lower end of the outer tube 12. In this case, a gap between the upper surface of the outer edge of the flange 61d and the lower end of the outer tube 12 is airtightly sealed.

The thermal insulator 62 is provided in the second space A2. The thermal insulator 62 is installed, for example, on the lid 14. The thermal insulator 62 prevents heat radiation from the opening at the lower end of the process container 10. The thermal insulator 62 has a structure obtained by molding a fibrous thermal insulation material into a cylindrical shape. The thermal insulator 62 may also have a structure obtained by stacking thermal insulation plates, which are made of, for example, quartz or silicon carbide, and are arranged at intervals in the vertical direction with a horizontal posture.

The heater 63 includes a ceiling plate heater 63a, an outer cylinder heater 63b, and an injector heater 63c. The heater 63 may also include other heaters.

The ceiling plate heater 63a is provided between the ceiling wall 61c and the thermal insulator 62. Providing the ceiling plate heater 63a improves the vertical uniformity of heat within the process container 10. The ceiling plate heater 63a has an annular plate shape, for example. The ceiling plate heater 63a may be, for example, a carbon-based heater. In this case, it is possible to achieve improved heating/cooling characteristics, leading to a shortened temperature recovery time. The ceiling plate heater 63a may be a heater other than the carbon-based heater. Since the second space A2 is partitioned from the first space A1, a less expensive heater such as a sheath heater or Kanthal wire heater may be used. In this case, it is possible to achieve significant cost savings compared to using the carbon-based heater.

The outer cylinder heater 63b is installed between the outer wall 61b and the thermal insulator 62. The outer cylinder heater 63b serves to heat the outer wall 61b. This may prevent the adhesion of by-products to a surface of the outer wall 61b. The outer cylinder heater 63b has a cylindrical shape, for example, and is installed on the lid 14. The outer cylinder heater 63b may be, for example, a sheath heater. In this case, it is easier to heat the outer wall 61b made of quartz through the emission of far-infrared rays.

The injector heater 63c is installed between the outer wall 61b and the thermal insulator 62. The injector heater 63c has a rod shape extending in the vertical direction. The injector heater 63c is installed at the same angular position as the gas injector 31 in the circumferential direction of the process container 10, for example. In this case, it is possible to heat the processing gas before it is discharged from each gas discharge hole 31h, which may prevent a decrease in the temperature of the processing gas discharged toward the substrate W held at the bottom of the substrate holder 18.

The radiation panel 64 is installed between the ceiling wall 61c and the ceiling plate heater 63a. The radiation panel 64 absorbs radiant heat from the substrate W side before dissipating it downward, thereby radiating the heat toward the substrate W side. This allows for the efficient heating of the substrate W. The radiation panel 64 is made of, for example, alumina or silicon carbide. In this case, the high emissivity of the radiation panel 64 may improve the heating efficiency of the substrate W.

The reflector 65 is provided between the thermal insulator 62 and the ceiling plate heater 63a. The reflector 65 reflects unnecessary radiant heat downward of the ceiling plate heater 63a, thus improving the heating performance of the ceiling plate heater 63a. The reflector 65 is formed, for example, from a gold-plated panel. The gold-plated panel has high reflectivity, enabling the efficient reflection of unnecessary radiant heat downward of the ceiling plate heater 63a. The gold-plated panel is chemically stable, which makes it less prone to deterioration.

The plate 66 is installed on the ceiling wall 61c. The plate 66 is made of, for example, quartz. The plate 66 has a C-shape that is open to the exhaust port 11f side in a plane view from the axial direction of the process container 10. This creates a first gap G1, including at least an angular position where the exhaust port 11f is provided and a second gap G2 provided at an angular position excluding the first gap G1, in the circumferential direction of the process container 10 between a lower surface of the support 17 and an upper surface of the partition member 61.

The first gap G1 is wider than the second gap G2. In this case, the purge gas supplied to the narrow space B1 is directed to the exhaust port 11f through the first gap G1. Therefore, it is possible to prevent the purge gas supplied to the narrow space B1 from being introduced into the substrate holder 18, thereby reducing the impact on the heat treatment of the substrate W held by the substrate holder 18. As a result, the uniformity of heat treatment may be improved.

The exhaust port 11f may be provided to encompass at least the same height as the first gap G1. In this case, the purge gas having passed through the first gap G1 is easily directed to the exhaust port 11f. Further, the exhaust port 11f is formed in the inner tube 11 to extend from the first cylindrical portion 11a to the vicinity of the upper end of the second cylindrical portion 11c. Since a lower portion of the inner tube 11 has the larger second inner diameter than the first inner diameter by the enlarged diameter portion 11b, it is difficult for the purge gas having passed through the first gap G1 and the second gap G2 to be introduced into the substrate holder 18. In other words, the distance between the inner surface of the inner tube 11 and an outer peripheral surface of the stage 17b is sufficiently smaller than the distance between the inner surface of the inner tube 11 and the outer wall 61b of the partition member 61. Therefore, the purge gas flows into a space between the inner tube 11 and the outer wall 61b of the partition member 61 and is directed to the exhaust port 11f formed in the enlarged diameter portion 11b and the second cylindrical portion 11c. As a result, it is possible to prevent the purge gas from being introduced into the substrate holder 18, thereby reducing the impact on the heat treatment of the substrate W held by the substrate holder 18.

In addition, the first embodiment has described an example in which the exhaust port 11f extends from the first cylindrical portion 11a to the vicinity of the upper end of the second cylindrical portion 11c of the inner tube 11, but is not limited to this. The exhaust port 11f may be configured to extend from the first cylindrical portion 11a to the middle of the enlarged diameter portion 11b of the inner tube 11. The same operational effects may be achieved as long as the exhaust port 11f is formed at least up to the middle of the enlarged diameter portion 11b.

The lid 14 has a supply port 14a and an exhaust port 14b. The supply port 14a is an opening for supplying a temperature regulation fluid to the second space A2. The exhaust port 14b is an opening for discharging the temperature regulation fluid from the second space A2.

A supply pipe 71 is connected to the supply port 14a. The supply pipe 71 is provided with a supply source 72, a valve 73, a flow rate controller 74, a temperature regulator 75, and a valve 76 in this order from the upstream side. The supply source 72 is a supply source for a temperature regulation fluid. The temperature regulation fluid is, for example, a coolant such as air or nitrogen. The temperature regulation fluid may be a heat medium. The valve 73 opens or closes a flow path inside the supply pipe 71. The flow rate controller 74 controls the flow rate of the temperature regulation fluid flowing through the supply pipe 71. The flow rate controller 74 is, for example, a mass flow controller (MFC). The temperature regulator 75 adjusts the temperature of the temperature regulation fluid flowing through the supply pipe 71. The temperature regulator 75 includes, for example, an air cooler. The temperature regulator 75 may include a refrigerator. The valve 76 opens or closes the flow path inside the supply pipe 71.

An exhaust pipe 81 is connected to the exhaust port 14b. One end of the exhaust pipe 81 is connected to the exhaust port 14b, and the other end of the exhaust pipe 81 is located near an exhaust duct 83 in a loading chamber. The other end of the exhaust pipe 81 may be directly connected to the exhaust duct 83.

The loading chamber is located below the process container 10. The loading chamber is provided with a fan filter unit (FFU) 82 and the exhaust duct 83. The fan filter unit 82 supplies a clean gas to the loading chamber. The exhaust duct 83 is positioned opposite to the fan filter unit 82. The exhaust duct 83 sucks the clean gas supplied to the loading chamber. This ensures that the loading chamber is maintained in a clean atmosphere. In the loading chamber, the substrate W, which is a processing target, is loaded into the substrate holder 18. In the loading chamber, the processed substrate W is unloaded from the substrate holder 18.

A filter 84 is provided in the middle of the exhaust pipe 81. The filter 84 removes impurities contained in the temperature regulation fluid. This may prevent impurities from entering the loading chamber from the second space A2. The impurities include, for example, particles generated by the heating and thermal expansion of components provided in the second space A2.

The exhaust duct 83 is connected at the downstream side to, for example, the fan filter unit 82. This allows for the circulation of the clean gas. A heat exchanger 85 and a filter 86 are provided between the exhaust duct 83 and the fan filter unit 82. The heat exchanger 85 serves as, for example, a radiator to cool the clean gas and temperature regulation fluid discharged from the exhaust duct 83. The filter 86 removes impurities contained in the clean gas and temperature regulation fluid.

The controller 90 controls, for example, the operation of each component of the substrate processing apparatus 1. The controller 90 may be, for example, a computer. Further, a computer program that executes the operation of each component of the substrate processing apparatus 1 is stored in a storage medium. The storage medium may be, for example, a flexible disk, a compact disk, a hard disk, a flash memory, a DVD, etc.

As described above, according to the substrate processing apparatus 1, the lid 14 has the supply port 14a for supplying the temperature regulation fluid to the second space A2 and the exhaust port 14b for discharging the temperature regulation fluid from the second space A2. In this case, while continuously supplying the coolant from the supply port 14a to the second space A2, the coolant, which was made to a high temperature in the second space A2, may be discharged from the exhaust port 14b. Therefore, it is possible to shorten the cooling time of the thermal insulator 60. As a result, the waiting time until the temperature of the processed substrate W is lowered to a temperature suitable for unloading is shortened. Further, while continuously supplying the heat medium from the supply port 14a to the second space A2, the heat medium, which was made to a low temperature in the second space A2, may be discharged from the exhaust port 14b. Therefore, it is possible to shorten the heating time of the thermal insulator 60. As a result, the waiting time until the substrate W, which is a processing target, is heated to a processing possible temperature is shortened. In this way, according to the substrate processing apparatus 1, the heating/cooling time of the thermal insulator 60 may be shortened, leading to improved productivity.

Further, according to the substrate processing apparatus 1, the second space A2 is partitioned from the first space A1 by the thermal insulator 60. In this case, the coolant may be supplied to the second space A2 to cool the second space A2 during the execution of steps such as returning the first space A1 from a processing pressure to an atmospheric pressure and unloading the substrate holder 18 from the interior of the process container 10. Therefore, downtime may be reduced.

Further, according to the substrate processing apparatus 1, one end of the exhaust pipe 81 is connected to the exhaust port 14b, and the other end of the exhaust pipe 81 is located near the exhaust duct 83 in the loading chamber. In this case, the temperature regulation fluid inside the second space A2 is discharged near the exhaust duct 83. Therefore, the exhaust duct 83 may promptly recover the coolant, which was heated to a high temperature by the chamber heater 51, the ceiling plate heater 63a, the outer cylinder heater 63b, the injector heater 63c, etc. in the second space A2. This may prevent the interior of the loading chamber from becoming a high temperature. As a result, it is possible to prevent the internal temperature of the loading chamber from exceeding the heat resistance temperature of resin components and electrical components provided within the loading chamber.

### Second Embodiment

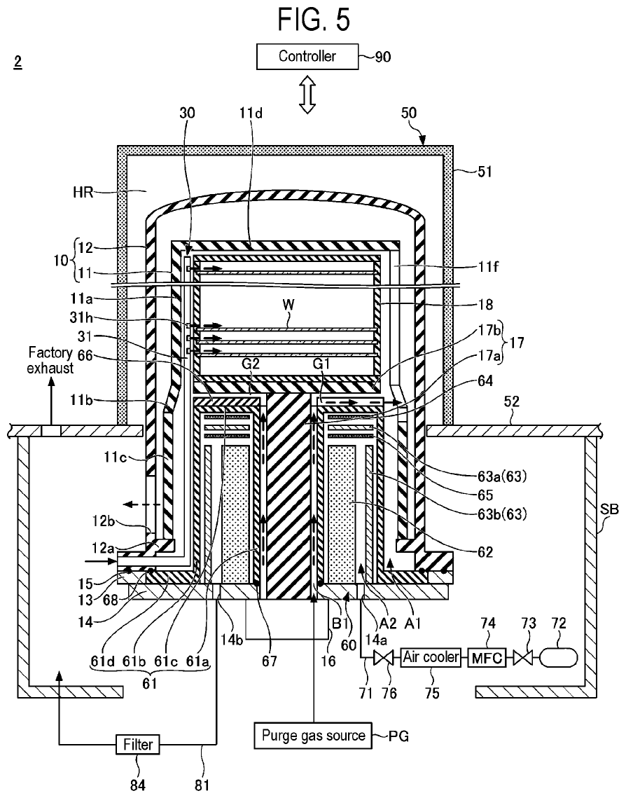

A substrate processing apparatus 2 according to a second embodiment will be described with reference to FIG. 5. FIG. 5 is a cross-sectional view illustrating the substrate processing apparatus 2 according to the second embodiment.

The substrate processing apparatus 2 mainly differs from the substrate processing apparatus 1 in that the other end of the exhaust pipe 81 is located within a scavenger SB. Other configurations are the same as those of the substrate processing apparatus 1. The following description will be focused on the configuration different from the substrate processing apparatus 1.

One end of the exhaust pipe 81 is connected to the exhaust port 14b, and the other end of the exhaust pipe 81 is located within the scavenger SB. The scavenger SB is installed on the base plate 52. The base plate 52 constitutes a ceiling of the loading chamber. The scavenger SB is installed in a periphery of the opening at the lower end of the process container 10. The base plate 52 is connected to an exhaust passage (not illustrated) that exhausts the internal atmosphere of the scavenger SB, which prevents the exhaust heat from the interior of the process container 10 from being transferred into the loading chamber. The exhaust passage is connected to a factory exhaust, for example. The exhaust passage may also be connected to the scavenger SB.

According to the substrate processing apparatus 2 as described above, the lid 14 has the supply port 14a for supplying the temperature regulation fluid to the second space A2 and the exhaust port 14b for discharging the temperature regulation fluid from the second space A2, similar to the substrate processing apparatus 1. This allows, as in the first embodiment, for shortening the heating/cooling time of the thermal insulator 60, leading to improved productivity.

Further, according to the substrate processing apparatus 2, the second space A2 is partitioned from the first space A1 by the thermal insulator 60, similar to the substrate processing apparatus 1. Thus, downtime may be reduced as in the first embodiment.

Further, according to the substrate processing apparatus 2, one end of the exhaust pipe 81 is connected to the exhaust port 14b, and the other end of the exhaust pipe 81 is located within the scavenger SB. In this case, the temperature regulation fluid inside the second space A2 is discharged to the factory exhaust through the exhaust passage connected to the scavenger SB. Therefore, it is possible to prevent the coolant, which was heated to a high temperature by the chamber heater 51, the ceiling plate heater 63a, the outer cylinder heater 63b, the injector heater 63c, etc. in the second space A2, from being introduced into the loading chamber. This may prevent the interior of the loading chamber from becoming a high temperature. As a result, it is possible to prevent the internal temperature of the loading chamber from exceeding the heat resistance temperature of resin components and electrical components provided within the loading chamber.

### Third Embodiment

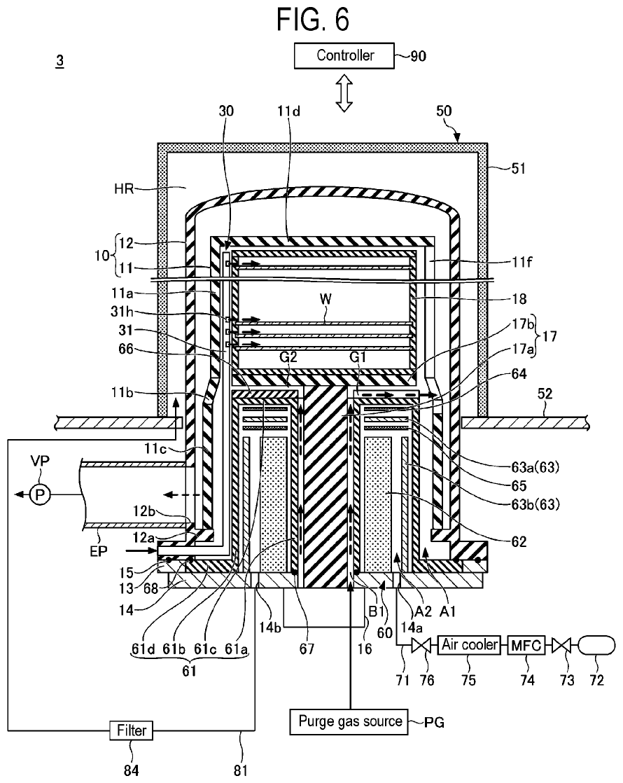

A substrate processing apparatus 3 according to a third embodiment will be described with reference to FIG. 6. FIG. 6 is a cross-sectional view illustrating the substrate processing apparatus 3 according to the third embodiment.

The substrate processing apparatus 3 mainly differs from the substrate processing apparatus 1 in that the other end of the exhaust pipe 81 is located within a heater chamber HR. Other configurations are the same as those of the substrate processing apparatus 1. The following description will be focused on the configuration different from the substrate processing apparatus 1.

One end of the exhaust pipe 81 is connected to the exhaust port 14b, and the other end of the exhaust pipe 81 is located within the heater chamber HR. The heater chamber HR is a space defined by the outer tube 12, chamber heater 51, and base plate 52. The heater chamber HR is located above the loading chamber and between the outer tube 12 and the chamber heater 51. The heater chamber HR is connected to an exhaust passage (not illustrated) that exhausts the internal atmosphere. The exhaust passage is connected to a factory exhaust, for example.

According to the substrate processing apparatus 3 as described above, the lid 14 has the supply port 14a for supplying the temperature regulation fluid to the second space A2 and the exhaust port 14b for discharging the temperature regulation fluid from the second space A2, similar to the substrate processing apparatus 1. This allows, as in the first embodiment, for shortening the heating/cooling time of the thermal insulator 60, leading to improved productivity.

Further, according to the substrate processing apparatus 3, the second space A2 is partitioned from the first space A1 by the thermal insulator 60, similar to the substrate processing apparatus 1. Thus, downtime may be reduced as in the first embodiment.

Further, according to the substrate processing apparatus 3, one end of the exhaust pipe 81 is connected to the exhaust port 14b, and the other end of the exhaust pipe 81 is located within the heater chamber HR. In this case, the temperature regulation fluid inside the second space A2 is discharged to the factory exhaust through the exhaust passage connected to the heater chamber HR. Therefore, it is possible to prevent the coolant, which was heated to a high temperature by the chamber heater 51, the ceiling plate heater 63a, the outer cylinder heater 63b, the injector heater 63c, etc. in the second space A2, from being introduced into the loading chamber. As a result, it is possible to prevent the internal temperature of the loading chamber from exceeding the heat resistance temperature of resin components and electrical components provided within the loading chamber.

### Fourth Embodiment

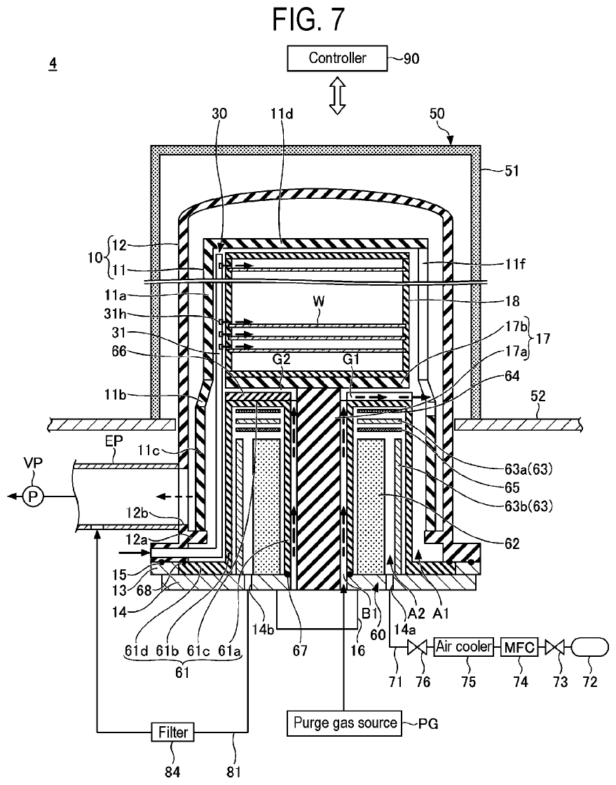

A substrate processing apparatus 4 according to a fourth embodiment will be described with reference to FIG. 7. FIG. 7 is a cross-sectional view illustrating the substrate processing apparatus 4 according to the fourth embodiment.

The substrate processing apparatus 4 mainly differs from the substrate processing apparatus 1 in that the other end of the exhaust pipe 81 is connected to the exhaust pipe EP. Other configurations are the same as those of the substrate processing apparatus 1. The following description will be focused on the configuration different from the substrate processing apparatus 1.

One end of the exhaust pipe 81 is connected to the exhaust port 14b, and the other end of the exhaust pipe 81 is connected to the exhaust pipe EP. In this case, the second space A2 may be depressurized to a vacuum state by the vacuum pump VP connected to the exhaust pipe EP.

According to the substrate processing apparatus 4 as described above, the lid 14 has the supply port 14a for supplying the temperature regulation fluid to the second space A2 and the exhaust port 14b for discharging the temperature regulation fluid from the second space A2, similar to the substrate processing apparatus 1. This allows, as in the first embodiment, for shortening the heating/cooling time of the thermal insulator 60, leading to improved productivity.

Further, according to the substrate processing apparatus 4, the second space A2 is partitioned from the first space A1 by the thermal insulator 60, similar to the substrate processing apparatus 1. Thus, downtime may be reduced as in the first embodiment.

Further, according to the substrate processing apparatus 4, one end of the exhaust pipe 81 is connected to the exhaust port 14b and the other end of the exhaust pipe 81 is connected to the exhaust pipe EP. In this case, the vacuum pump VP connected to the exhaust pipe EP may depressurize the interior of the second space A2, which prevents convection within the second space A2, leading to improved thermal insulation performance. Further, the pressure difference between the first space A1 and the second space A2 is reduced, resulting in a lower strength required for the partition member 61. Therefore, the thickness of the partition member 61 may be reduced. As a result, it is possible to shorten the heating/cooling time of the thermal insulator 60 owing to a reduction in the heat capacity of the partition member 61.

In addition, the other end of the exhaust pipe 81 may be connected to an exhaust pipe different from the exhaust pipe EP, and may be depressurized by a vacuum pump connected to that exhaust pipe.

### Fifth Embodiment

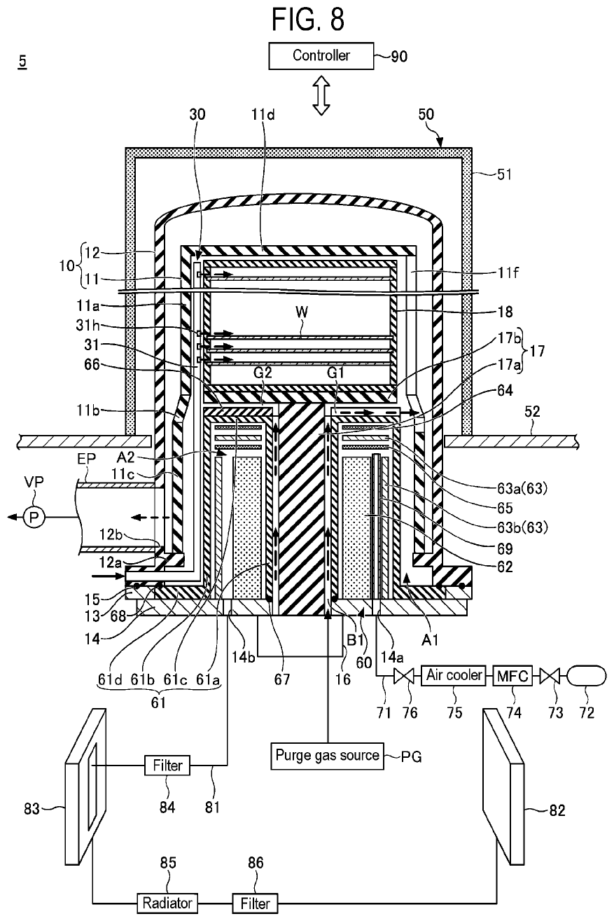

A substrate processing apparatus 5 according to a fifth embodiment will be described with reference to FIG. 8. FIG. 8 is a cross-sectional view illustrating the substrate processing apparatus 5 according to the fifth embodiment.

The substrate processing apparatus 5 mainly differs from the substrate processing apparatus 1 in that the thermal insulator 60 has a guide member 69 that directs the temperature regulation fluid, supplied from the supply port 14a to the second space A2, upward of the second space A2. Other configurations are the same as those of the substrate processing apparatus 1. The following description will be focused on the configuration different from the substrate processing apparatus 1.

The guide member 69 is installed in the second space A2. The guide member 69 guides the temperature regulation fluid, which is supplied from the supply port 14a to the second space A2, upward of the second space A2. The guide member 69 has a tubular shape extending vertically, for example, between the thermal insulator 62 and the outer cylinder heater 63b. A lower end of the guide member 69 is located in a vicinity of the supply port 14a. The lower end of the guide member 69 may be connected to the supply port 14a. An upper end of the guide member 69 is located at an upper portion of the second space A2. The upper end of the guide member 69 is located, for example, at a height between an upper surface of the thermal insulator 62 and a lower surface of the reflector 65.

According to the substrate processing apparatus 5 as described above, the lid 14 has the supply port 14a for supplying the temperature regulation fluid to the second space A2 and the exhaust port 14b for discharging the temperature regulation fluid from the second space A2, similar to the substrate processing apparatus 1. This allows, as in the first embodiment, for shortening the heating/cooling time of the thermal insulator 60, leading to improved productivity.

Further, according to the substrate processing apparatus 5, the second space A2 is partitioned from the first space A1 by the thermal insulator 60, similar to the substrate processing apparatus 1. Thus, downtime may be reduced as in the first embodiment.

Further, according to the substrate processing apparatus 5, one end of the exhaust pipe 81 is connected to the exhaust port 14b and the other end of the exhaust pipe 81 is located in a vicinity of the exhaust duct 83 in the loading chamber, similar to the substrate processing apparatus 1. This may prevent the internal temperature of the loading chamber from exceeding the heat resistance temperature of resin components and electrical components provided within the loading chamber.

Further, according to the substrate processing apparatus 5, the thermal insulator 60 includes the guide member 69 that guides the temperature regulation fluid, which is supplied from the supply port 14a to the second space A2, upward of the second space A2. In this case, by supplying the coolant from the supply port 14a to the second space A2, the coolant supplied to the second space A2 is directed upward of the second space A2 through the guide member 69. This allows for the rapid cooling of the substrate W held by the substrate holder 18 provided above the thermal insulator 60. Therefore, the waiting time until the temperature of the processed substrate W is lowered to a temperature suitable for unloading is shortened.

The embodiments disclosed herein should be considered to be exemplary and not limitative in all respects. The above embodiments may be omitted, replaced or modified in various embodiments without departing from the scope of the appended claims and their gist.

According to the present disclosure, it is possible to shorten the heating/cooling time of a thermal insulator.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a process container accommodating a substrate holder that holds a plurality of substrates and including an opening at a lower end of the process container;
a lid configured to open and close the opening; and
a thermal insulator installed on the lid and configured to thermally insulate a first space below the substrate holder,
wherein the thermal insulator includes a partition member that forms a second space partitioned from the first space, and
wherein the lid includes a supply port for supplying a temperature regulation fluid to the second space and an exhaust port for discharging the temperature regulation fluid from the second space.

2. The substrate processing apparatus of claim 1, wherein the thermal insulator includes a guide member that guides the temperature regulation fluid, which is supplied to the second space, upward of the second space.

3. The substrate processing apparatus of claim 2, further comprising a pipe including one end connected to the exhaust port and the other end connected to an exhaust location outside the process container.

4. The substrate processing apparatus of claim 3, wherein the exhaust location is an exhaust duct that exhausts a loading chamber.

5. The substrate processing apparatus of claim 3, wherein the exhaust location is a scavenger in a periphery of the opening.

6. The substrate processing apparatus of claim 3, wherein the exhaust location is a heater chamber between the process container and a heater that heats the process container from a periphery of process container.

7. The substrate processing apparatus of claim 3, wherein the exhaust location is an exhaust pipe that exhausts an interior of the process container.

8. The substrate processing apparatus of claim 1, further comprising a pipe including one end connected to the exhaust port and the other end connected to an exhaust location outside the process container.

9. The substrate processing apparatus of claim 8, wherein the exhaust location is an exhaust duct that exhausts a loading chamber.

10. The substrate processing apparatus of claim 8, wherein the exhaust location is a scavenger in a periphery of the opening.

11. The substrate processing apparatus of claim 8, wherein the exhaust location is a heater chamber between the process container and a heater that heats the process container from a periphery of process container.

12. The substrate processing apparatus of claim 8, wherein the exhaust location is an exhaust pipe that exhausts an interior of the process container.
